(19) United States
(12) Patent Application Publication
(10) Pub. No.: US 2020/0098549 A1
(43) Pub. Date: Mar. 26, 2020

(54) HEAT CONDUCTIVE SPACER FOR PLASMA PROCESSING CHAMBER

(71) Applicant: Applied Materials, Inc., Santa Clara, CA (US)

(72) Inventors: Beom Soo PARK, San Jose, CA (US); Robin L. TINER, Santa Cruz, CA (US); Jianheng LI, Santa Clara, CA (US); Sang Jeong OH, Sunnyvale, CA (US); Lai ZHAO, Campbell, CA (US); Gaku FURUTA, Sunnyvale, CA (US); Soo Young CHOI, Fremont, CA (US); Jeevan Prakash SEQUEIRA, Milpitas, CA (US); Wei-Ting CHEN, Taipei City (TW); Hsiao-Ling YANG, Taipei City (TW); Cheng-Hang HSU, Taoyuan City (TW); Won Ho SUNG, Asan-si (KR); Hyun Young HONG, Chungcheongnam-do (KR)

(21) Appl. No.: 16/143,280

(22) Filed: Sep. 26, 2018

(51) Int. Cl. H01J 37/32; C23C 16/505

(52) U.S. Cl. CPC H01J 37/32522; H01J 37/3244; C23C 16/505; H01J 37/32862; H01J 2237/3321; H01J 2237/3323; H01J 2237/3325; H01J 2237/002

(57) ABSTRACT

A plasma processing chamber includes a chamber body and a lid assembly coupled to the chamber body to define a processing volume. The lid assembly includes a backing plate coupled to the chamber body, a diffuser with a plurality of openings formed therethrough, and a heat conductive spacer disposed between and coupled to the backing plate and the diffuser to transfer heat from the diffuser to the backing plate. The plasma processing chamber further includes a substrate support disposed within the processing volume.

### BACKGROUND

### Field

Embodiments of the present disclosure generally relate to a system and apparatus for substrate processing. More specifically, embodiments of the present disclosure relate to a heat conductive spacer for use within a lid assembly of a plasma processing chamber.

### Description of the Related Art

Plasma processing, such as plasma-enhanced chemical vapor deposition (PECVD), is commonly employed to deposit thin films on substrates to form electronic devices. As technology advances, device geometries and structures formed on substrates continue to increase in complexity.

Additionally, the demand for electronic devices, such as larger displays and solar panels, also continues to grow and, in turn, so does the size of the substrates that are used to fabricate such devices. Accordingly, manufacturing processes, such as large-area PECVD processes, must continue to improve in order to meet the increasingly difficult demands of attaining uniformity and desired film properties.

One challenge faced by large-area PECVD processing is plasma non-uniformity within the plasma processing chamber. Various factors and elements, such as heat, may cause the plasma within the plasma processing chamber to bend in the areas proximate the edge of the substrate. Such bending of the plasma causes non-uniform processing of the substrate.

Accordingly, an apparatus that facilitates improved uniformity of a deposition process performed in a plasma processing chamber is needed.

### SUMMARY

The present disclosure generally relates to an apparatus for plasma processing. More specifically, the present disclosure relates to an apparatus for providing plasma uniformity across the surface of a substrate during processing.

In one embodiment, a plasma processing chamber includes a chamber body and a lid assembly coupled to the chamber body to define a processing volume. The lid assembly includes a backing plate coupled to the chamber body, a diffuser with a plurality of openings formed therethrough, and a heat conductive spacer disposed between and coupled to the backing plate and the diffuser to transfer heat from the diffuser to the backing plate. The plasma processing chamber further includes a substrate support disposed within the processing volume.

In another embodiment, a lid assembly for a plasma processing chamber includes a backing plate, a diffuser with a plurality of openings formed therethrough, and a heat conductive spacer disposed between and coupled to the backing plate and the diffuser to transfer heat from the diffuser to the backing plate.

In yet another embodiment, a lid assembly for a plasma processing chamber includes a backing plate, a diffuser with a plurality of openings formed therethrough and a cooling flow channel formed therein to receive coolant, and a heat conductive spacer. The heat conductive spacer has a rectangular cross-section that is disposed between and in direct contact with a bottom surface of the backing plate and a top surface of the diffuser to transfer heat from the diffuser to the backing plate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a plasma processing chamber in accordance with one or more embodiments of the present disclosure.

FIG. 2 is an exploded perspective view of a lid assembly for a plasma processing chamber in accordance with one or more embodiments of the present disclosure.

FIG. 3 is a perspective sectional view of a lid assembly for a plasma processing chamber in accordance with one or more embodiments of the present disclosure.

FIG. 4 is a schematic cross-sectional view of a lid assembly for a plasma processing chamber in accordance with one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to an apparatus and method for processing substrates. In one aspect, a plasma processing chamber is provided that includes a chamber body and a lid assembly to define a processing volume within plasma processing chamber. The lid assembly includes a backing plate, a diffuser, and a heat conductive spacer disposed between and coupled to the backing plate and the diffuser. A substrate support is also disposed within the processing volume. The heat conductive spacer is used to transfer heat from the diffuser and to the backing plate. As such, the heat conductive spacer is in direct contact with a top surface of the diffuser and a bottom surface of the backing plate, and the heat conductive spacer is formed from or includes a heat conductive material. The heat conductive spacer has a rectangular cross-section, in which a width of the heat conductive spacer is equal to or larger than a thickness of the diffuser. The plasma processing chamber further includes an RF power source coupled to the lid assembly, and a gas source and a remote plasma source in fluid communication with the processing volume through the lid assembly.

The embodiments described herein may be used with any types of deposition processes and are not limited to use for substrate plasma processing chambers. The embodiments described herein may be used with various types, shapes, and sizes of masks and substrates. Further, the substrate is not limited to any particular size or shape. In one aspect, the term “substrate” refers to any polygonal, squared, rectangular, curved or otherwise circular or non-circular workpiece, such as a glass or polymer substrate used in the fabrication of flat panel displays, for example.

In the description that follows, the terms “gas” and “gases” are used interchangeably, unless otherwise noted, and refer to one or more precursors, reactants, catalysts, carrier gases, purge gases, cleaning gases, effluent, combinations thereof, as well as any other fluid.

Embodiments disclosed herein are illustratively described below in reference to a PECVD system configured to process large area substrates, such as a PECVD system, available from AKT, a division of Applied Materials, Inc., Santa Clara, Calif. However, it should be understood that the embodiments have utility in other system configurations such as etch systems, other chemical vapor deposition systems and any other system in which distributing gas within a process chamber is desired, including those systems configured to process round substrates.

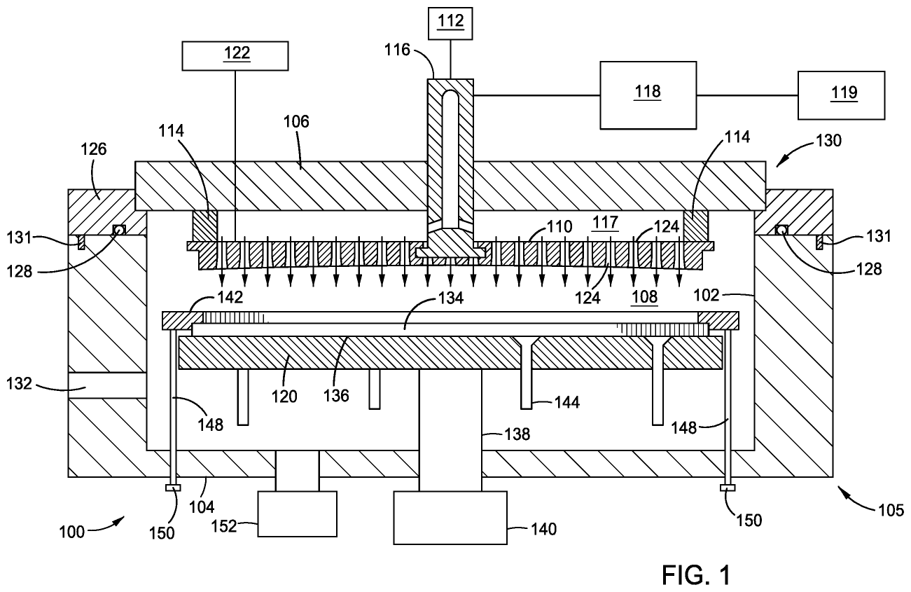

FIG. 1 is a schematic sectional view of a plasma processing chamber 100. The chamber 100 is operable to perform a deposition process for an encapsulation layer by a PECVD process. It is noted that the chamber 100 of FIG. 1 is just an exemplary apparatus that may be used to form electronic devices on a substrate. One suitable chamber for a PECVD process is available from Applied Materials, Inc., located in Santa Clara, Calif. It is contemplated that other deposition chambers, including those from other manufacturers, may be utilized to practice the embodiments.

The plasma processing chamber 100 generally includes walls 102 and a bottom 104 that define a body 105 of the chamber 100. The body 105 and a lid assembly 130 are used to define a processing volume 108. The lid assembly 130 includes a backing plate 106 and a gas distribution plate or diffuser 110. The diffuser 110 includes openings 124 formed therethrough, and the diffuser 110 may also be referred to as a faceplate or a showerhead. The diffuser 110 is coupled to the backing plate 106 as a periphery thereof by a spacer 114. The spacer 114, which is discussed more below, is formed of or includes a heat conductive material, and is used to transfer heat from the diffuser 110 to the backing plate 106. The spacer 114 is also used to define a plenum 117 between the backing plate 106 and the diffuser 110.

Precursor gases from a gas source 112 are provided to the plenum 117 by a conduit 116. Gases from the plenum 117 are flowed to the processing volume 108 via the openings 124 of the diffuser 110. A remote plasma source 118, such as an inductively coupled remote plasma source, is coupled to the conduit 116. A radio frequency (RF) power source 122 is coupled to the backing plate 106 and/or to the diffuser 110 to provide RF power to the diffuser 110. The RF power source 122 is used to generate an electric field between the diffuser 110 and a substrate support 120. The electric field is used to form a plasma from the gases present between the diffuser 110 and the substrate support 120 within the processing volume 108. Various RF frequencies may be used, such as a frequency between about 0.3 MHz and about 200 MHz. In one embodiment, the RF power source 122 provides power to the diffuser 110 at a frequency of 13.56 MHz.

The backing plate 106 rests on a lid plate 126, which rests on the walls 102 of the chamber 100. A seal 128, such as an elastomeric O-ring, is provided between the walls 102 and the lid plate 126. The lid plate 126, the backing plate 106, and components coupled thereto, such as the diffuser 110, the heat conductive spacer 114, and the conduit 116, may define the lid assembly 130. The lid assembly 130 may also include portions positioned thereon or attached thereto, such as the RF power source 122 and the remote plasma source 118. The lid assembly 130 may be removable from the body 105, and the lid assembly 130 may be aligned with the body 105 by indexing pins 131.

Referring still to the plasma processing chamber 100 of FIG. 1, the processing volume 108 is accessed through a sealable slit valve opening 132 formed through the walls 102. As such, a substrate 134 may be transferred in and out of the processing volume 108 through the slit valve opening 132. The substrate support 120 includes a substrate receiving surface 136 for supporting the substrate 134, in which a stem 138 is coupled to a lift system 140 to raise and lower the substrate support 120.

A mask frame 142 is shown as included with the chamber 100, in which the mask frame 142 may be placed over periphery of the substrate 134 during processing. The mask frame 142 includes a plurality of mask screens coupled thereto that include fine openings corresponding to devices or layers formed on the substrate 134. Substrate lift pins 144 are moveably disposed through the substrate support 120 to move the substrate 134 to and from the substrate receiving surface 136 to facilitate substrate transfer. The substrate support 120 may also include heating and/or cooling elements to maintain the substrate support 120 and substrate 134 positioned thereon at a desired temperature.

Support members 148 are also shown as disposed at least partially in the processing volume 108. The support members 148 may also serve as alignment and/or positioning devices for the mask frame 142. The support members 148 are coupled to a motor 150 that is operable to move the support members 148 relative to the substrate support 120, and thus position the mask frame 142 relative to the substrate 134. A vacuum pump 152 is coupled to the chamber 100 to control the pressure within the processing volume 108.

Between processing substrates, a cleaning gas from a clean gas source 119 may be provided to the remote plasma source 118. When excited, a remote plasma is formed from which dissociated cleaning gas species are generated. The plasma of the cleaning gases is provided to the processing volume 108 through the conduit 116 and through the openings 124 formed in the diffuser 110 to clean components of the plasma processing chamber 100. The cleaning gas may be further excited by the RF power source 122 provided to flow through the diffuser 110 to reduce recombination of the dissociated cleaning gas species. Suitable cleaning gases include but are not limited to NF₃, F₂, and SF₆.

Uniformity of plasma distribution is generally desired during processing, pre-treatment, and/or post-treatment of the substrate 134. The distribution of the plasma on the substrate 134 is determined by a variety of factors, such as distribution of the gases, geometry of the processing volume 108, the distance between the lid assembly 130 and the substrate support 120, variations between deposition processes on the same substrate or different substrates, differences in deposition processes and cleaning processes, and even the current temperature of components included within the plasma processing chamber 100.

For example, the diffuser 110 increases in temperature with each subsequent and consecutive or continuous use, particularly with a temperature difference between the edge or periphery of the diffuser 110 and a center of the diffuser 110. This increased and/or non-uniform temperature for the diffuser 110 affects the plasma within the processing volume 108 and the plasma distribution on the substrate 134, thereby leading to non-uniform thickness of layers formed on the substrate 134. Accordingly, the heat conductive spacer 114, which is used to transfer heat from the diffuser 110 to the backing plate 106, may be able to transfer heat away from the diffuser 110 to facilitate a more uniform plasma distribution on the substrate 134.

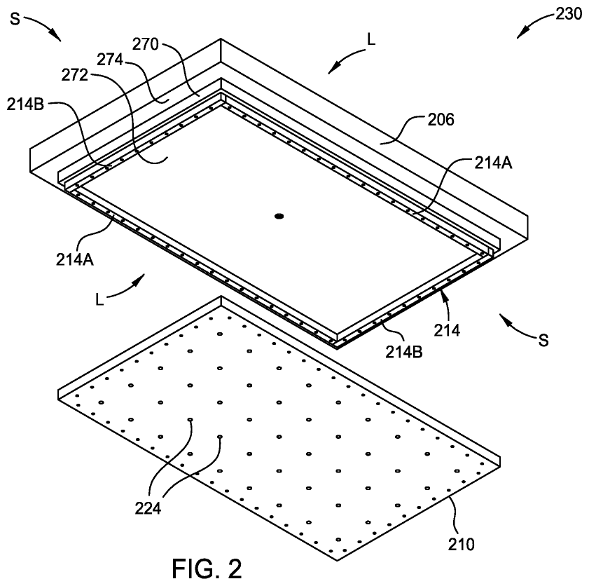

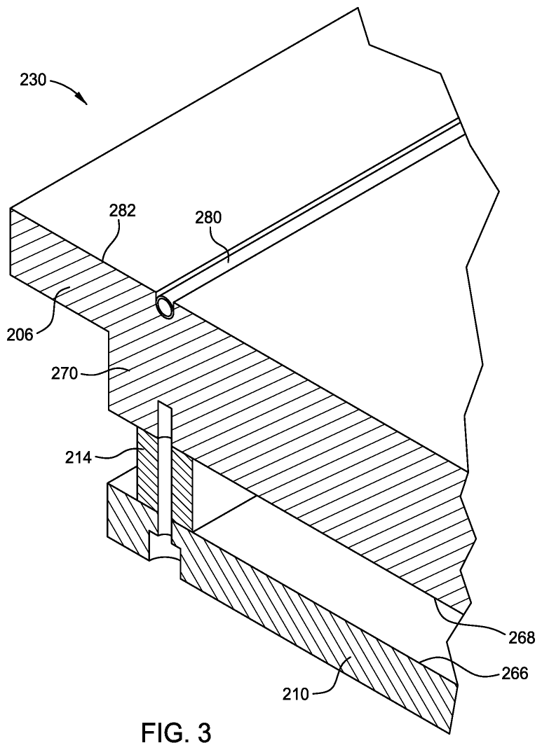

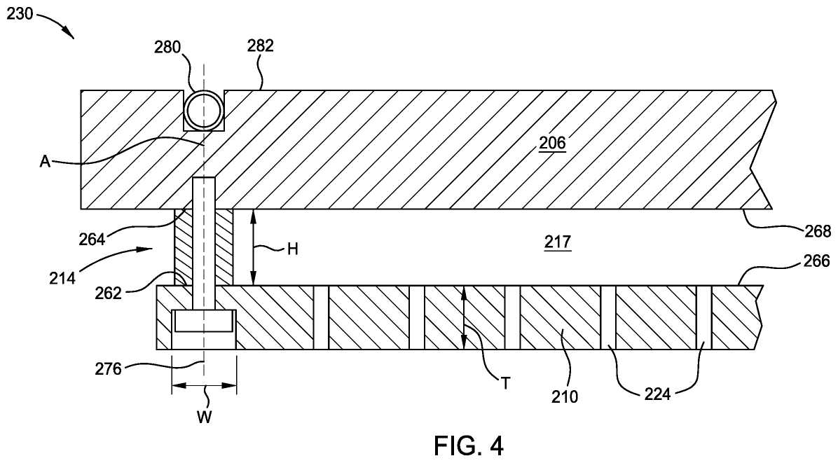

Referring now to FIGS. 2-4, multiple views of a lid assembly 230 in accordance with one or more embodiments of the present disclosure are shown. In particular, FIG. 2 shows an exploded perspective view of the lid assembly 230, FIG. 3 shows a perspective sectional view of the lid assembly 230, and FIG. 4 shows a schematic cross-sectional view of the lid assembly 230. The lid assembly 230 may be similar to the lid assembly 130, and thus may include one or more components similar to the lid assembly 130 discussed above.

Accordingly, the lid assembly 230 includes a backing plate 206, a diffuser 210, and a heat conductive spacer 214. The backing plate 206 includes a conduit 216 coupled or formed therethrough that is coupled to one or more gas or plasma sources, as discussed above. The diffuser 210 includes openings 224 formed therethrough to distribute the contents from the conduit 216 into a processing volume of a plasma processing chamber. Further, the lid assembly 230 is shown as having a rectangular shape defined by a pair of parallel long sides L and a pair of parallel short sides S. The short sides S and the long sides L are perpendicular to one another. However, the lid assembly 230 may be other shapes, such as square, circular, elliptical, or other useful shapes without departing from the scope of the present disclosure.

The heat conductive spacer 214 is disposed between and coupled to the backing plate 206 and the diffuser 210. In particular, the heat conductive spacer 214 is disposed about a periphery of the diffuser 210 and defines a plenum 217 between the backing plate 206 and the diffuser 210. For example, as best shown in FIG. 2, the heat conductive spacer 214 includes a pair of long sides 214A and a pair of short sides 214B corresponding to the long sides L and short sides S of the lid assembly 230 for the heat conductive spacer 214 to be disposed about the periphery of the diffuser 210.

The heat conductive spacer 214 is used to facilitate the transfer of heat from the diffuser 210 to the backing plate 206. The heat conductive spacer 214, thus, is in direct contact with the backing plate 206 and the diffuser 210. The heat conductive spacer 214 is shown as having a rectangular cross-section, though the spacer 214 is not so limited, and other shapes may be used for the cross-section of the spacer 214. As such, as best shown in FIG. 4, the heat conductive spacer 214 includes a bottom surface 262 and a top surface 264, in which the bottom surface 262 is in direct contact with a top surface 266 of the diffuser 210 and the top surface 264 is in direct contact with a bottom surface 268 of the backing plate 206. The backing plate 206 may also include a step 270 formed in the bottom surface 268 thereof, such as shown in FIGS. 2 and 3 to define an interior surface 272 and an exterior surface 274 on the bottom surface 268. The heat conductive spacer 214 is shown as in direct contact with the periphery of the interior surface 272 of the backing plate 206. However, the present disclosure is not so limited, as the bottom surface 264 may have no step formed therein or may be substantially planar.

Further, the heat conductive spacer 214 may have dimensions to facilitate heat transfer from the diffuser 210 to the backing plate 206. The heat conductive spacer 214 is shown as having a height H and a width W. Further, the diffuser 210 is shown as having a thickness T, though the thickness T of the diffuser 210 may vary. For example, the diffuser 210 may have an increased thickness near the periphery or edge and a decreased thickness near the center. The heat conductive spacer 214 is shown as having the width W as equal to or larger than the thickness T of the diffuser 210, particularly at the periphery of the diffuser 210. The heat conductive spacer 214 may also have the height H as equal to or larger than the thickness T of the diffuser 210. The increased width W and/or height H for the heat conductive spacer 214, such as with respect to the diffuser 210, increases the thermal contact between the spacer 214 and the diffuser 210 and facilitates the transfer of heat from the diffuser 210 to the spacer 214.

The heat conductive spacer 214 is formed from or includes a heat conductive material, such as a metal. An example of a heat conductive metal includes copper, nickel, steel, and aluminum. The backing plate 206 is formed from or includes metal, such as aluminum, and similarly the diffuser 210 is formed from or includes metal, such as aluminum. Thus, the heat conductive spacer 214, the backing plate 206, and the diffuser 210 may each be formed from aluminum.

The backing plate 206 may include one or more cooling flow channels 280 formed therein, such as to receive coolant. The cooling flow channel 280 is used to transfer heat away from the backing plate 206 through coolant flowing through the cooling flow channel 280. FIGS. 3 and 4 show the cooling flow channel 280 formed within a top surface 282 of the backing plate 206. Thus, heat transferred to the backing plate 206 from the diffuser 210 through the heat conductive spacer 214 is subsequently transferred away from the backing plate 206 through the cooling flow channel 280. An example of a coolant includes water, ethylene glycol, a coolant sold under the tradename GALDEN®, or any other suitable coolant.

Further, in one or more embodiments, the heat conductive spacer 214 may be in alignment, such as in vertical alignment, with the cooling flow channel 280. For example, as shown in FIG. 4, the heat conductive spacer 214 and the cooling flow channel 280 are in alignment with respect to each other along line A, which extends vertically through the cooling flow channel 280, the backing plate 206, the conductive spacer 214, and the diffuser 210. The vertical alignment of the of the heat conductive spacer 214 and the cooling flow channel 280 facilitates the transfer of heat from the heat conductive spacer 214 and away from the backing plate 206 through the cooling flow channel 280.

One or more fasteners 276 are used to couple the heat conductive spacer 214 between the backing plate 206 and the diffuser 210. For example, as shown in FIG. 4, the fastener 276 extends from the diffuser 210, through the heat conductive spacer 214, and to the backing plate 206 to couple the heat conductive spacer 214 between the backing plate 206 and the diffuser 210. The fastener 276 may include a screw as shown, a bolt and a nut, and/or any other fastener known in the art. Further, the fastener 276 may be formed from or include a heat conductive material, such as metal, and particularly aluminum.

As discussed above, a heat conductive spacer in accordance with the present disclosure may be able to transfer heat away from a diffuser within a plasma processing chamber. For example, in a plasma processing chamber without the heat conductive spacer, the diffuser rose in temperature from about 75° C. to about 120° C. after multiple continuous depositions and uses of the plasma processing chamber. Comparatively, in a plasma processing chamber with a heat conductive spacer in accordance with the present disclosure, the diffuser only rose in temperature from about 75° C. to about 90° C. after the same multiple continuous depositions and uses of the plasma processing chamber. Thus, the heat conductive spacer facilitated a transfer of about 90° C. of heat away from the diffuser. This reduction in heat and temperature for the diffuser enables may increase the uniformity of distribution of plasma within the processing volume of the plasma processing chamber, thereby increasing uniformity of thickness of layers formed on a substrate with the plasma processing chamber.

While the foregoing is directed to embodiments of the present disclosure, other and further embodiments of the disclosure may be devised without departing from the basic scope thereof, and the scope thereof is determined by the claims that follow.

What is claimed is:

1. A plasma processing chamber, comprising:
a chamber body;
a lid assembly coupled to the chamber body defining a processing volume, the lid assembly comprising:
a backing plate coupled to the chamber body;
a diffuser comprising a plurality of openings formed therethrough; and
a heat conductive spacer disposed between and coupled to the backing plate and the diffuser to transfer heat from the diffuser to the backing plate; and
a substrate support disposed within the processing volume.

2. The plasma processing chamber of claim 1, wherein the heat conductive spacer is in direct contact with a top surface of the diffuser and a bottom surface of the backing plate.

3. The plasma processing chamber of claim 2, wherein:
the heat conductive spacer comprises a rectangular cross-section; and
a width of the heat conductive spacer is equal to or larger than a thickness of the diffuser.

4. The plasma processing chamber of claim 1, wherein the heat conductive spacer comprises aluminum.

5. The plasma processing chamber of claim 1, further comprising a plurality of fasteners extending through the heat conductive spacer to couple the heat conductive spacer between the backing plate and the diffuser.

6. The plasma processing chamber of claim 5, wherein the backing plate, the diffuser, and the fasteners each comprise aluminum.

7. The plasma processing chamber of claim 1, wherein the heat conductive spacer is disposed about a periphery of the diffuser and defines a plenum between the backing plate and the diffuser.

8. The plasma processing chamber of claim 7, wherein the heat conductive spacer comprises a pair of long sides and a pair of short sides.

9. The plasma processing chamber of claim 1, wherein the backing plate comprises a cooling flow channel formed therein to receive coolant.

10. The plasma processing chamber of claim 9, wherein the heat conductive spacer is in vertical alignment with at least a portion of the cooling flow channel.

11. The plasma processing chamber of claim 1, further comprising an RF power source coupled to the lid assembly.

12. The plasma processing chamber of claim 1, further comprising a gas source and a remote plasma source in fluid communication with the processing volume through the lid assembly.

13. A lid assembly for a plasma processing chamber, comprising:
a backing plate;
a diffuser comprising a plurality of openings formed therethrough; and
a heat conductive spacer disposed between and coupled to the backing plate and the diffuser to transfer heat from the diffuser to the backing plate.

14. The lid assembly of claim 13, further comprising a lid plate with the backing plate coupled to the lid plate.

15. The lid assembly of claim 13, wherein the backing plate, the diffuser, and the heat conductive spacer each comprise aluminum.

16. The lid assembly of claim 13, wherein:
the heat conductive spacer is in direct contact with a top surface of the diffuser and a bottom surface of the backing plate;
the heat conductive spacer comprises a rectangular cross-section; and
a width of the heat conductive spacer is equal to or larger than a thickness of the diffuser.

17. The lid assembly of claim 13, wherein:
the heat conductive spacer is disposed about a periphery of the diffuser and defines a plenum between the backing plate and the diffuser; and
the heat conductive spacer comprises a pair of long sides and a pair of short sides.

18. The lid assembly of claim 13, wherein:
the backing plate comprises a cooling flow channel formed therein to receive coolant; and
the heat conductive spacer is in vertical alignment with at least a portion of the cooling flow channel.

19. A lid assembly for a plasma processing chamber, comprising:
a backing plate;
a diffuser comprising a plurality of openings formed therethrough and a cooling flow channel formed therein to receive coolant; and
a heat conductive spacer comprising a rectangular cross-section that is disposed between and in direct contact with a bottom surface of the backing plate and a top surface of the diffuser to transfer heat from the diffuser to the backing plate.

20. The lid assembly of claim 19, wherein the backing plate, the diffuser, and the heat conductive spacer each comprise aluminum.
